(19) United States
(12) Patent Application Publication
(10) Pub. No.: US 2025/0253295 A1
(43) Pub. Date: Aug. 7, 2025

(54) DISPLAY DEVICE AND MANUFACTURING METHOD THEREOF

(71) Applicant: LG Display Co., Ltd., Seoul (KR)

(72) Inventors: Jongha JAE, Paju-si (KR); Hanyoung YANG, Paju-si (KR); ChungHwan AN, Paju-si (KR); JungEun SON, Paju-si (KR); Jinho KIM, Paju-si (KR)

(21) Appl. No.: 18/770,311

(22) Filed: Jul. 11, 2024

(30) Foreign Application Priority Data
Feb. 6, 2024 (KR) 10-2024-0017854

(51) Int. Cl. H01L 27/15; H01L 21/683; H01L 33/00

(52) U.S. Cl. CPC H01L 25/0753; H01L 21/6835; H01L 25/167; H10H 20/01; H10H 20/857; H01L 2221/68354; H01L 2221/68368

(57) ABSTRACT

The present disclosure relates to a display device and manufacturing method thereof. A display device includes a substrate in which a pixel including a plurality of sub pixels is included. The display device includes a first planarization layer disposed on the substrate and configured to have an opening. The display device includes an adhesive layer disposed on the first planarization layer. The display device includes a plurality of light emitting diodes disposed on the adhesive layer in each of the plurality of sub pixels. The adhesive layer includes a plurality of first areas configured to overlap the plurality of light emitting diodes, a plurality of non-attachment areas disposed respectively to be adjacent to the first areas, and a second area as a remaining part, except for the plurality of first areas and non-attachment areas.

### CROSS-REFERENCE TO RELATED APPLICATIONS

This application claims the priority of Korean Patent Application No. 10-2024-0017854 filed on Feb. 6, 2024, in the Korean Intellectual Property Office, the disclosure of which is incorporated herein by reference.

### BACKGROUND

### Technical Field

The present disclosure relates to a display device and a manufacturing method thereof, and more particularly, to a display device and a manufacturing method thereof using a light emitting diode (LED).

### Description of the Related Art

Display devices used for the monitor of a computer, a TV, a mobile phone and the like include an organic light emitting display (OLED) and the like that emit light on its own, and a liquid crystal display (LCD) and the like that require a separate light source.

Display devices have been applied in a variety of fields such as a personal mobile device as well as the monitor of a computer, a TV and the like, and research has been conducted into display devices that ensure a decrease in the volume thereof and is lightweight, while securing a wide active area.

Recently, display devices including a light emitting diode LED have drawn attention as a next-generation display device. An LED is included of an inorganic material rather than an organic material, and ensures high reliability and has a longer lifespan than a liquid crystal display or an organic light emitting diode. Further, the LED exhibits excellent luminous efficiency, strong impact resistance and high reliability, as well as ensuring a fast lighting speed, and displays an image of high luminance.

### BRIEF SUMMARY

Various embodiments of the present disclosure provide a display device and a manufacturing method thereof that selectively transfers a part of a plurality of light emitting diodes of a donor to an area corresponding to sub pixels.

Various embodiments of the present disclosure provide a display device and a manufacturing method thereof in which a double step is formed in an area to which light emitting diodes are not transferred in a transfer process, and then the non-transfer area is exposed to light, such that a transfer area only has an adhesive force.

Various embodiments of the present disclosure provide a display device and a manufacturing method thereof that secures a simplified transfer process and a reduction in the time taken for the processing.

Various embodiments of the present disclosure provide a display device ad a manufacturing method thereof in which a plurality of transfer processes is performed in succession with one donor.

Various embodiments of the present disclosure provide a display device and a manufacturing method thereof that selectively transfers a part of a plurality of light emitting diodes of a donor to an area corresponding to sub pixels.

A display device according to an exemplary embodiment of the present disclosure may include: a substrate in which a pixel including a plurality of sub pixels is included; a first planarization layer configured to have an opening disposed on the substrate; an adhesive layer disposed on the first planarization layer; and a plurality of light emitting diodes disposed on the adhesive layer in each of the plurality of sub pixels, wherein the adhesive layer may include a plurality of first areas configured to overlap the plurality of light emitting diodes, a plurality of non-attachment areas disposed respectively to be adjacent to the first areas, and a second area as a remaining part, except for the plurality of first areas and non-attachment areas.

A manufacturing method of a display device according to another exemplary embodiment of the present disclosure may include: transferring a plurality of light emitting diodes on a wafer to a donor; disposing a first planarization layer on a substrate of a display panel; patterning the first planarization layer and forming an opening; disposing an adhesive layer on the first planarization layer; disposing a mask on the adhesive layer and irradiating light; and transferring the plurality of light emitting diodes on the donor to a display panel, wherein the adhesive layer may be included of a plurality of first areas that overlap the mask and a non-attachment area which is exposed from the mask and to which light is irradiated, the opening may overlap the plurality of first areas and the non-attachment area, and among the plurality of light emitting diodes, light emitting diodes contacting the plurality of first areas may only be transferred to the display panel.

Other detailed matters of the exemplary embodiments are included in the detailed description and the drawings.

According to the present disclosure, the first areas of the adhesive layer, overlapping the light emitting diodes, may only have an adhesive force, such that only a part of the plurality of light emitting diodes of the donor is transferred selectively.

According to the present disclosure, the adhesive force of the first areas of the adhesive layer, corresponding to the light emitting diodes, may be improved, such that a transfer failure is reduced or minimized.

According to the present disclosure, a plurality of transfer processes may be performed in succession with one donor, such that the number of processes of transferring the light emitting diodes to the donor from a wafer and time taken for the processing decrease.

The effects of the present disclosure are not limited to the aforementioned effects, and other effects, which are not mentioned above, will be apparently understood to a person having ordinary skill in the art from the following description.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic diagram of a display device of a first embodiment;

FIG. 2 is a partial cross-sectional view of the display device of the first embodiment;

FIG. 3 is a perspective view of a tiling display device of a first embodiment;

FIG. 4 is an enlarged plan view of the display device of the first embodiment;

FIG. 5 is a cross-sectional view of the display device of the first embodiment;

FIGS. 6A to 6I are flowcharts for describing a manufacturing method of a display device of a first embodiment;

FIGS. 7A to 7E are flowcharts for describing the manufacturing method of a display device of the first embodiment;

FIG. 8 is a cross-sectional view of a display device of a second embodiment;

FIG. 9A is a plan view of a display device of a second embodiment and a third embodiment;

FIGS. 9B to 9E are flowcharts for describing a manufacturing method of area A-A′ of FIG. 9A;

FIG. 10 is a cross-sectional view of the display device of the third embodiment;

FIGS. 11A to 11C are flowcharts for describing a manufacturing method of area A-A′ of FIG. 9A; and

FIG. 12 is a plan view of a display device of a fourth embodiment.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is referred to as being “on” another element or layer, it may be directly on the other element or layer, or intervening elements or layers may be present therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure. Like reference numerals generally denote like elements throughout the specification.

When ‘A’ overlaps ‘B,’ ‘A’ may overlap with ‘B’ from either a plan view or a cross-sectional view according to the context of the embodiments.

The features of various embodiments of the present disclosure can be partially or entirely coupled to or combined with each other and can be interlocked and operated in technically various ways, and respective embodiments can be carried out independently of or in association with each other.

Hereinafter, an exemplary embodiment of the present disclosure will be described in detail with reference to the drawings.

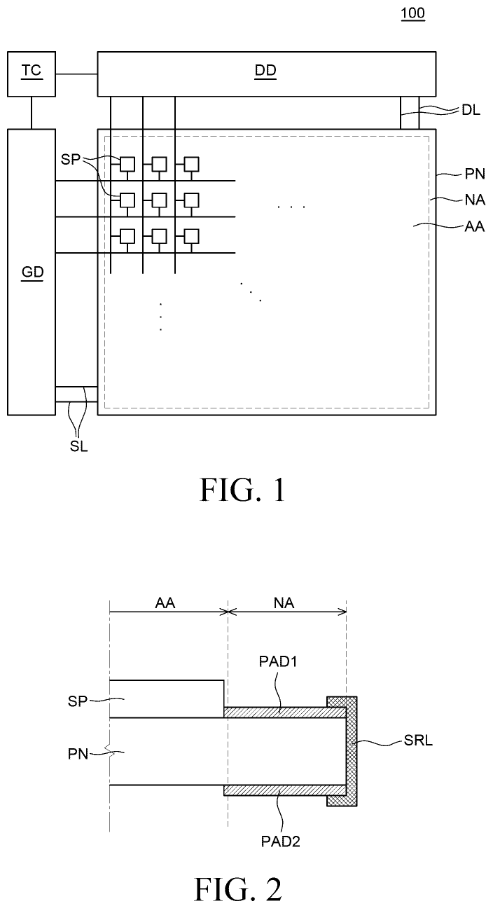

FIG. 1 is a schematic diagram of a display device of a first embodiment. In FIG. 1, among a variety of components of a display device 100, a display panel PN, a gate driver GD, a data driver DD and a timing controller TC are only illustrated for convenience of description.

Referring to FIG. 1, the display device 100 includes a display panel PN including a plurality of sub pixels SP, a gate driver GD and a data driver DD providing a variety of signals to the display panel PN, and a timing controller TC controlling the gate driver GD and the data driver DD.

The gate driver GD provides a plurality of scan signals to a plurality of scan lines SL, based on a plurality of gate control signals that are provided from the timing controller TC. In FIG. 1, one gate driver GD is disposed at one side of the display panel PN in such a way that the one gate driver GD is spaced from the display panel PN, but the number of the gate drivers GD and the positions of the gate drivers GD are not limited thereto.

The data driver DD converts image data input from the timing controller TC to a data voltage by using a reference gamma voltage based on a plurality of data control signals that are provided from the timing controller TC. The data driver DD may provide the converted data voltage to a plurality of data lines DL.

The timing controller TC arranges image data input from the outside and provides the arranged image data to the data driver DD. The timing controller TC may generate a gate control signal and a data control signal by using synchronization signals input from the outside, e.g., a dot clock signal, a data enable signal, and horizontal/vertical synchronization signals. Additionally, the timing controller TC may provide the generated gate control signal and the generated data control signal respectively to the gate driver GD and the data driver DD to control the gate driver GD and the data driver DD.

The display panel PN, as a component for displaying an image to the user, includes a plurality of sub pixels SP. In the display panel PN, the plurality of scan lines SL and the plurality of data lines DL cross each other, and each of the plurality of sub pixels SP connects to a scan line SL and a data line DL. Further, though not illustrated in the drawing, each of the plurality of sub pixels SP may connect to a high potential power line, a low potential power line, a reference line and the like.

In the display panel PN, an active area AA, and a non-active area NA adjacent to the active area AA may be defined.

The active area AA denotes an area where an image is displayed, in the display device 100. In the active area AA, a plurality of sub pixels SP constituting a plurality of pixels PX, and a circuit for driving the plurality of sub pixels SP may be disposed. The sub pixel SP is a minimum unit constituting the active area AA, and n numbers of sub pixels SP may constitute one pixel PX. In each of the plurality of sub pixels SP, a light emitting diode, a thin film transistor for driving the light emitting diode and the like may be disposed. A plurality of light emitting diodes may be defined in a different manner, depending on the sort of a display panel PN. For example, in the case where the display panel PN is an inorganic light emitting display panel, a light emitting diode 120 may be a light-emitting diode (LED) or a micro light-emitting diode (LED).

In the active area AA, a plurality of signal lines transmitting a variety of signals to the plurality of sub pixels SP may be disposed. For example, the plurality of signal lines may include a plurality of data lines DL providing a data voltage to each of the plurality of sub pixels SP, a plurality of scan lines SL providing a gate voltage to each of the plurality of sub pixels SP, and the like. The plurality of scan lines SL may extend in one direction and connect to the plurality of sub pixels SP, in the active area AA, and the plurality of data lines DL may extend in a direction different from the one direction and connect to the plurality of sub pixels SP, in the active area AA. Additionally, in the active area AA, a low potential power line, a high potential power line, and the like may be further disposed but not limited thereto.

The non-active area NA is an area where an image is not displayed, and may be defined as an area that extends from the active area AA. In the non-active area NA, a link line and a pad electrode for transmitting a signal to a sub pixel SP of the active area AA or a driving IC such as a gate driver IC or a data driver IC, and the like, may be disposed.

Additionally, the non-active area NA may be disposed on the rear surface of the display panel PN, e.g., a surface on which the sub pixels SP may not be disposed or may be omitted, and may not be limited to the one illustrated in the drawing.

Further, a driver such as the gate driver GD, the data driver DD and the timing controller TC may connect to the display panel PN in a variety of ways. For example, the gate driver GD may be mounted in the non-active area NA, based on a gate in panel (GIP) method, or may be mounted among the plurality of sub pixels SP, in the active area AA, based on a gate in active area (GIA) method. For example, the data driver DD and the timing controller TC may be formed on a separate flexible film and a separate printed circuit board, and electrically connect to the display panel PN in such a way that the flexible film and the printed circuit board are bonded to the pad electrode formed in the non-active area NA of the display panel PN. In the case where the gate driver GD is mounted based on the GIP method, while the data driver DD and the timing controller TC transmit a signal to the display panel PN through the pad electrode of the non-active area NA, the surface area of the non-active area NA, which is large enough to dispose the gate driver GD and the pad electrode, needs to be ensured such that a bezel may increase.

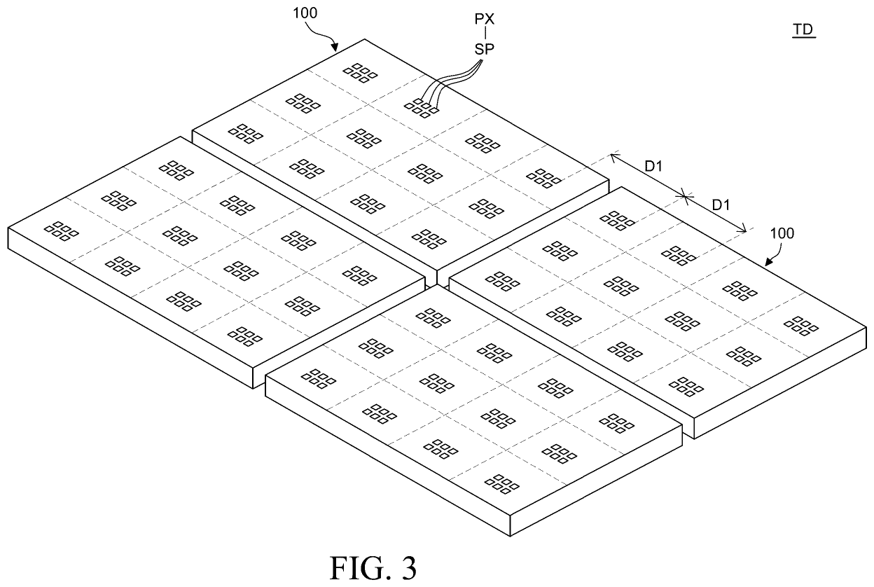

On the contrary, in the case where the gate driver GD is mounted in the active area AA, based on the GIA method, while a side line SRL connecting a signal line on the front surface of the display panel PN with the pad electrode on the rear surface of the display panel PN is formed to bond a flexible film and a printed circuit board to the rear surface of the display panel PN, the non-active area NA on the front surface of the display panel PN may be reduced or minimized. That is, in the case where the gate driver GD, the data driver DD and the timing controller TC connect to the display panel PN as described above, a zero bezel may be implemented such that no bezel is present substantially. Detailed description in relation to this is provided with reference to FIGS. 2 and 3.

FIG. 2 is a partial cross-sectional view of the display device of the first embodiment. FIG. 3 is a perspective view of a tiling display device of a first embodiment.

In the non-active area NA of the display panel PN, a plurality of pad electrodes for transmitting a variety of signals to the plurality of sub pixels SP are disposed. For example, a first pad PAD1 transmitting a signal to the plurality of sub pixels SP is disposed in the non-active area NA on the front surface of the display panel PN, and a second pad PAD2 electrically connecting to a driving component such as a flexible film and a printed circuit board is disposed in the non-active area NA on the rear surface of the display panel PN.

At this time, a variety of signal lines, e.g., a scan line SL or a data line DL and the like, connecting to the plurality of sub pixels SP, may extend from the active area AA to the non-active area NA and electrically connect to the first pad electrode PAD1, though not illustrated in the drawings.

Additionally, the side line SRL is disposed along the lateral surface of the display panel PN. The side line SRL may connect the first pad electrode PAD1 on the front surface of the display panel PN and the second pad electrode PAD2 on the rear surface of the display panel PN electrically. Accordingly, a signal from the driving component on the rear surface of the display panel PN may be transmitted to the plurality of sub pixels SP through the second pad electrode PAD2, the side line SRL and the first pad electrode PAD1. Thus, a signal transmission path from the front surface of the display panel PN to the lateral and rear surfaces thereof may be formed such that the surface area of the non-active area NA of the display panel PN is reduced or minimized.

Referring to FIG. 3, a tiling display device TD having a large screen may be implemented in such a way that a plurality of display devices 100 are connected. At this time, in the case where the tiling display device TD is implemented by using a display device 100 the bezel of which is reduced or minimized as illustrated in FIG. 2, a seam area between a display device 100 and a display device 100 where an image is not displayed is reduced or minimized, thereby ensuring improvement in display quality.

For example, the plurality of sub pixels SP may constitute one pixel PX, and a distance D1 between outermost pixels PX of one display device 100 may be the same as a distance D1 between pixels PX in one display device 100. Thus, a distance between pixels PX between a display device 100 and a display device 100 may be constant, such that the seam area is reduced or minimized.

However, embodiments of FIGS. 2 and 3 are provided as examples, and the display device 100 according to the embodiment may be an ordinary display device having a bezel and not limited thereto.

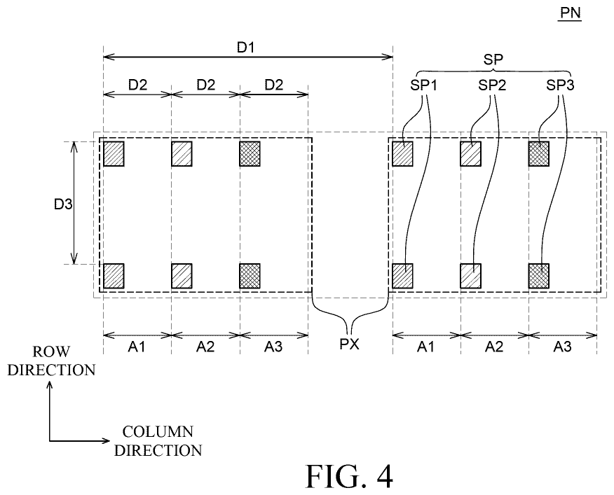

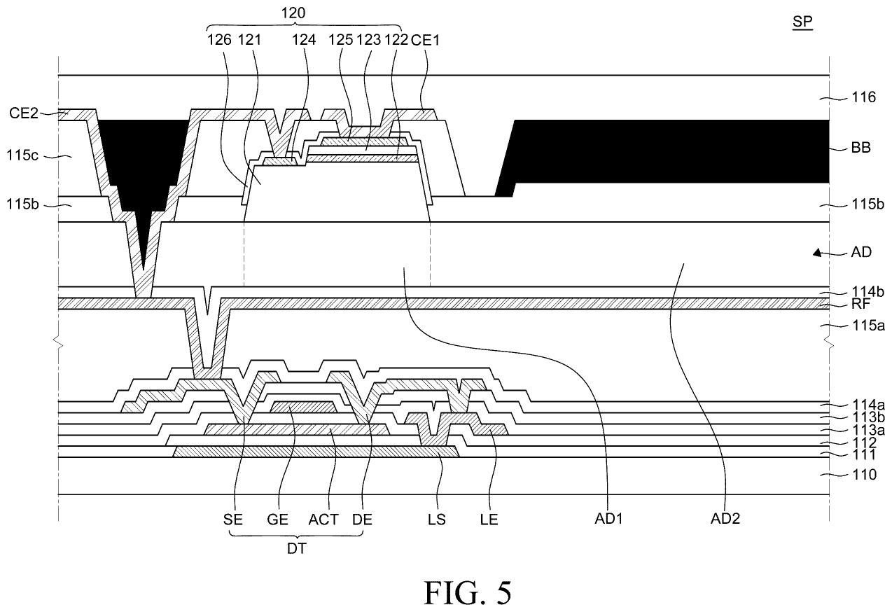

FIG. 4 is an enlarged plan view of the display device of the first embodiment. FIG. 5 is a cross-sectional view of the display device of the first embodiment.

Referring to FIG. 4, each display panel PN includes a plurality of pixels PX included of a plurality of sub pixels SP. Each of the plurality of sub pixels SP may include a light emitting diode and a pixel circuit, and emit light independently. For example, a first sub pixel SP1 may be a red sub pixel, a second sub pixel SP2 may be a green sub pixel, and a third sub pixel SP3 may be a blue sub pixel, but not limited thereto.

One pixel PX may include one or more of first sub pixels SP1, one or more of second sub pixels SP2 and one or more of third sub pixels SP3. For example, one pixel PX may be included of two first sub pixels SP1, two second sub pixels SP2 and two third sub pixels SP3.

Hereinafter, suppose that one pixel PX includes a pair of first sub pixels SP1, a pair of second sub pixels SP2 and a pair of third sub pixels SP3. However, the configuration of a pixel is not limited to the above configuration.

A plurality of sub pixels SP included in one pixel PX may be disposed to form a pair of rows. For example, one first sub pixel SP1, one second sub pixel SP2 and one third sub pixel SP3 may be consecutively arranged in a first row, and the remaining first sub pixel SP1, the remaining second sub pixel SP2 and the remaining third sub pixel SP3 may be consecutively arranged in a second row.

In one column, one sort of sub pixel SP may only be disposed. For example, in one pixel PX, the first sub pixel SP1 may only be disposed in a first column, the second sub pixel SP2 may only be disposed in a second column, and the third sub pixel SP3 may only be disposed in a third column. Additionally, an area corresponding to a column in which the first sub pixel SP1 is disposed may be defined as a first area A1, an area corresponding to a column in which the second sub pixel SP2 is disposed may be defined as a second area A2, and an area corresponding to a column in which the third sub pixel SP3 is disposed may be defined as a third area A3.

The plurality of pixels PX may be disposed with a regular gap in the row direction. For example, the plurality of pixels PX may be disposed with a first length D1 gap in the row direction. That is, the pitch between pixels PX may be the first length D1. Further, though not illustrated in the drawing, the plurality of pixels PX may also be disposed with a regular gap in the column direction.

In one pixel PX, the sub pixels SP disposed in the same row may be disposed with a regular gap. For example, in one pixel PX, the sub pixels SP disposed in the same row may be disposed with a second length D2 gap. In other words, the widths of each of a plurality of first areas A1, each of a plurality of second areas A2 and each of a plurality of third areas A3 may correspond to the second length D2. Further, in one pixel PX, the sub pixels SP disposed in the same column may be disposed with a third length D3 gap.

Hereinafter, referring to FIG. 5, a substrate 110, a buffer layer 111, a gate insulation layer 112, a first interlayer insulation layer 113a, a second interlayer insulation layer 113b, a first passivation layer 114a, a first planarization layer 115a, a second passivation layer 114b, an adhesive layer AD, a second planarization layer 115b, a third planarization layer 115c, a protective layer 116, a bank BB, a driving transistor DT, a light emitting diode 120, a reflective layer RF, a first connection electrode CE1, a second connection electrode CE2, a light shielding layer LS and an auxiliary electrode LE are disposed in each of the plurality of sub pixels SP of the display panel PN of the display device 100 according to the first embodiment.

The substrate 110, as a component for supporting a variety of components included in the display device 100, may be made of an insulation material. For example, the substrate 110 may be made of glass or resin and the like. Additionally, the substrate 110 may be made of polymer or plastic or made of a material having flexibility.

On the substrate 110, a light shielding layer LS is disposed in each of the plurality of sub pixels SP. The light shielding layer LS blocks light under the substrate 110 from being input to a semiconductor layer ACT of the driving transistor DT described hereinafter. The light shielding layer LS blocks light from being input to the semiconductor layer ACT of the driving transistor DT, thereby reducing or minimizing leakage current.

The buffer layer 111 is disposed on the substrate 110 and the light shielding layer LS. The buffer layer 111 may reduce moisture or impurities that are infiltrated through the substrate 110. The buffer layer 111, for example, may be included of a single layer or multiple layers of silicon oxide (SiOx) or silicon nitride (SiNx), but not limited thereto. However, the buffer layer 111 may be omitted depending on the sort of a substrate 110 or the sort of a transistor, and not limited thereto.

The driving transistor DT is disposed on the buffer layer 111. The driving transistor DT includes a semiconductor layer ACT, a gate electrode GE, a source electrode SE and a drain electrode DE.

The semiconductor layer ACT is disposed on the buffer layer 111. The semiconductor layer ACT may be made of a semiconductor material such as an oxide semiconductor, amorphous silicon or polysilicon, but not limited thereto.

The gate insulation layer 112 is disposed on the semiconductor layer ACT. The gate insulation layer 112, as an insulation layer for insulating the semiconductor layer ACT from the gate electrode GE, may be included of a single layer or multiple layers of silicon oxide (SiOx) or silicon nitride (SiNx), but not limited thereto.

The gate electrode GE is disposed on the gate insulation layer 112. The gate electrode GE may be included of a conductive material, e.g., copper Cu, aluminum Al, molybdenum Mo, nickel Ni, titanium Ti, chromium Cr or an alloy thereof, but not limited thereto.

The first interlayer insulation layer 113a and the second interlayer insulation layer 113b are disposed on the gate electrode GE. The first interlayer insulation layer 113a and the second interlayer insulation layer 113b have a contact hole for allowing each of the source electrode SE and the drain electrode DE to access the semiconductor layer ACT. The first interlayer insulation layer 113a and the second interlayer insulation layer 113b, as an insulation layer for protecting the configurations thereunder, may be included of a single layer or multiple layers of silicon oxide (SiOx) or silicon nitride (SiNx), but not limited thereto.

The source electrode SE and the drain electrode DE electrically connecting to the semiconductor layer ACT are disposed on the second interlayer insulation layer 113b. The source electrode SE and the drain electrode DE may be included of a conductive material, e.g., copper Cu, aluminum Al, molybdenum Mo, nickel Ni, titanium Ti, chromium Cr or an alloy thereof, but not limited thereto.

Additionally, according to the present disclosure, the first interlayer insulation layer 113a and the second interlayer insulation layer 113b, e.g., a plurality of insulation layers, are disposed among the gate electrode GE, the source electrode SE and the drain electrode DE, but one insulation layer may only be disposed among the gate electrode GE, the source electrode SE and the drain electrode DE, and not limited thereto.

Further, in the case where a plurality of insulation layers such as the first interlayer insulation layer 113a and the second interlayer insulation layer 113b are disposed among the gate electrode GE, the source electrode SE and the drain electrode DE as illustrated in the drawing, an electrode may be additionally formed between the first interlayer insulation layer 113a and the second interlayer insulation layer 113b, and the additionally formed electrode may form a capacitor, together with another component disposed under the first interlayer insulation layer 113a or on the second interlayer insulation layer 113b.

The auxiliary electrode LE is disposed on the gate insulation layer 112. The auxiliary electrode LE is an electrode electrically connecting the light shielding layer LS under the buffer layer 111 to any one of the source electrode SE and the drain electrode DE on the second interlayer insulation layer 113b. For example, since the light shielding layer LS electrically connects to any one of the source electrode SE or the drain electrode DE through the auxiliary electrode LE and does not operate as a floating gate, a change in the threshold voltage of the driving transistor DT, caused by the light shielding layer LS having floated, may be reduced or minimized. In the drawing, the light shielding layer LS connects to the drain electrode DE, but the light shielding layer LS may connect to the source electrode SE and not limited thereto.

The first passivation layer 114a is disposed on the driving transistor DT. The first passivation layer 114a, as an insulation layer for protecting the configuration thereunder, may be included of a single layer or multiple layers of silicon oxide (SiOx) or silicon nitride (SiNx), but not limited thereto.

The first planarization layer 115a is disposed on the first passivation layer 114a. The first planarization layer 115a may planarize the upper portion of the substrate 110 on/over which the driving transistor DT is disposed. The first planarization layer 115a may be included of a single layer or multiple layers, and for example, may be made of photoresist or an acryl-based organic material, but not limited thereto.

The reflective layer RF is disposed on the first planarization layer 115a. The reflective layer RF may reflect light emitted from the light emitting diode 120 toward the upper portion of the light emitting diode 120 while electrically connecting the light emitting diode 120 to the driving transistor DT. The reflective layer RF is made of a conductive material having an excellent reflection property, to reflect light emitted from the light emitting diode 120 toward the upper portion of the light emitting diode 120.

The second passivation layer 114b is disposed on the reflective layer RF. The second passivation layer 114b, as an insulation layer for protecting the configuration thereunder, may be included of a single layer or multiple layers of silicon oxide (SiOx) or silicon nitride (SiNx), but not limited thereto.

The adhesive layer AD is disposed on the second passivation layer 114b. The adhesive layer AD may be coated on the front surface of the substrate 110 and fix the light emitting diode 120 disposed on the adhesive layer AD. The adhesive layer AD may be made of a photocurable adhesive material that is cured by light. For example, the adhesive layer AD may be made of an acryl-based material including a photosensitizer, but not limited thereto. The adhesive layer AD may be formed on the front surface of the display panel PN except for an area where a pad electrode is disposed. For example, in the case where a plurality of first pad electrodes PAD1 are formed on the front surface of the display panel PN as illustrated in FIG. 2, the adhesive layer AD may be formed in the remaining area of the front surface of the display panel PN, except for the area where the first pad electrodes PAD1 are formed.

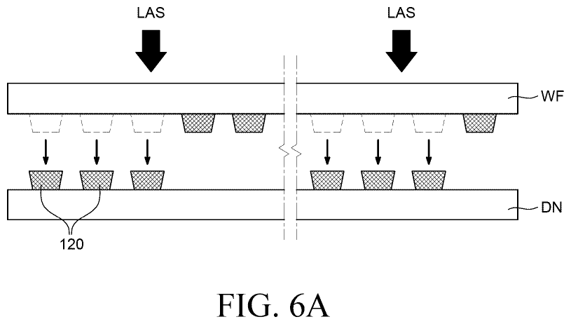

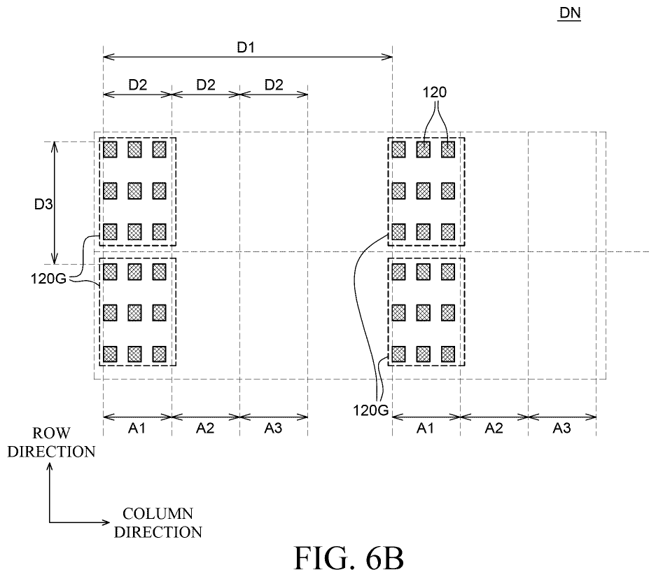

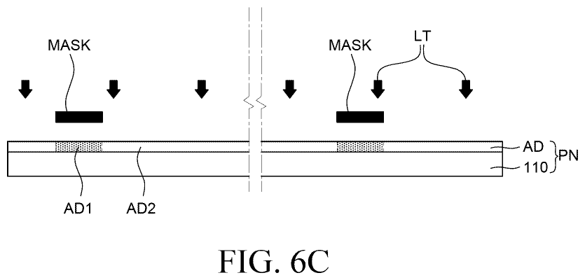

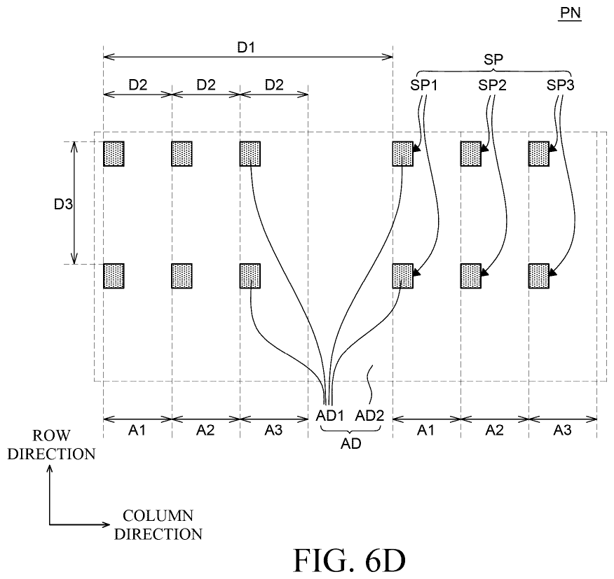

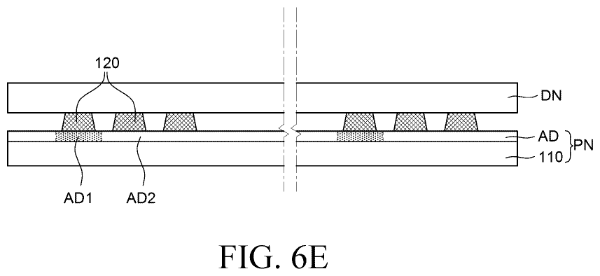

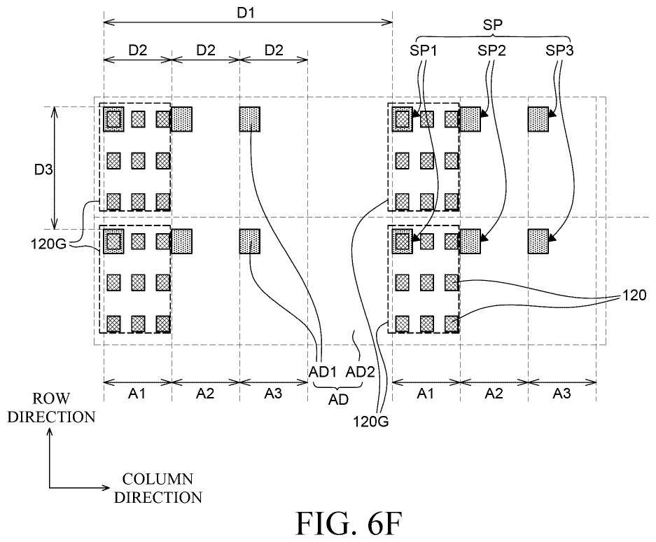

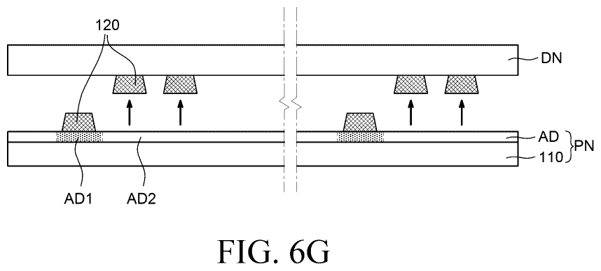

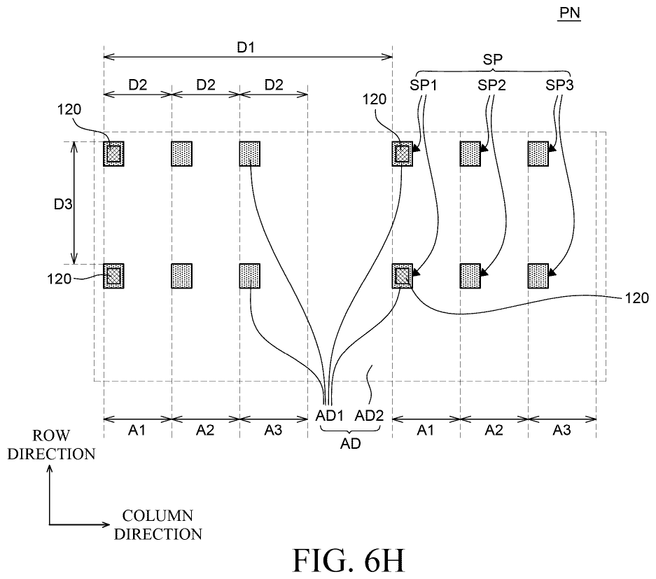

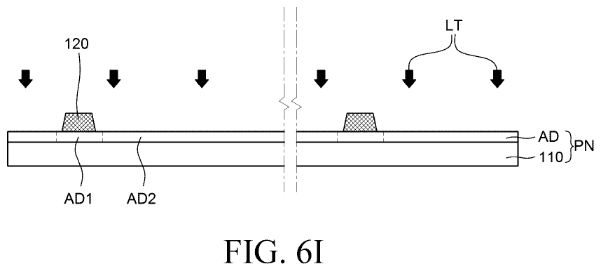

The adhesive layer AD may be included of a plurality of first areas AD1 that overlaps the plurality of light emitting diodes 120 and a second area AD2 that is the remaining area except for the plurality of first areas AD1. The second area AD2 of the adhesive layer AD may be cured before the light emitting diodes 120 are transferred to the display panel PN, and the plurality of first areas AD1 of the adhesive layer AD may be cured after the light emitting diodes 120 are transferred to the display panel PN. The plurality of first areas AD1 and the second area AD2 of the adhesive layer AD are cured at different timing such that among a plurality of light emitting diodes 120 disposed on a donor, light emitting diodes 120 overlapping the plurality of sub pixels SP are only selectively transferred to the display panel PN. Detailed description in relation to this is provided hereinafter with reference to FIGS. 6A to 6I.

A plurality of light emitting diodes 120 are disposed in each of the plurality of sub pixels SP, on the adhesive layer AD. The plurality of light emitting diodes 120 may include a light emitting diode 120 emitting red light, green light, blue light and the like, as an element that emits light by using current, and based on a combination of the light, may implement light of a variety of colors including white. For example, the plurality of light emitting diodes 120 may be a light emitting diode (LED) or a micro LED, but not limited thereto.

The light emitting diode 120 includes a first semiconductor layer 121, a light emitting layer 122, a second semiconductor layer 123, a first electrode 124, a second electrode 125 and an encapsulation film 126.

The first semiconductor layer 121 is disposed on the adhesive layer AD, and the second semiconductor layer 123 is disposed on the first semiconductor layer 121. The first semiconductor layer 121 and the second semiconductor layer 123 may be layers that are formed in such a way that a specific material is doped with an n-type impurity and a p-type impurity. For example, each of the first semiconductor layer 121 and the second semiconductor layer 123 may be layers in which a material such as gallium nitride (GaN), indium aluminum phosphide (InAlP), gallium arsenide (GaAs) and the like is doped with an n-type impurity and a p-type impurity. Additionally, the p-type impurity may be magnesium, zinc Zn, beryllium Be and the like, and the n-type impurity may be silicon Si, germanium, tin Sn and the like, but not limited thereto.

The light emitting layer 122 is disposed between the first semiconductor layer 121 and the second semiconductor layer 122. The light emitting layer 122 may receive a hole and an electron from the first semiconductor layer 121 and the second semiconductor layer 123 to emit light. The light emitting layer 122 may have a single-layered structure or a multi-quantum well (MQW) structure, and for example, may be made of indium gallium nitride (InGaN) or gallium nitride (GaN) and the like, but not be limited thereto.

The first electrode 124 is disposed on the first semiconductor layer 121. The first electrode 124 is an electrode for connecting the driving transistor DT and the first semiconductor layer 121 electrically. The first electrode 124 may be disposed on the upper surface of the first semiconductor layer 121, which is exposed from the light emitting layer 122 and the second semiconductor layer 123. The first electrode 124 may be included of a conductive material, e.g., a transparent conductive material such as indium tin oxide (ITO) or indium zinc oxide (IZO) and the like or an opaque conductive material such as titanium Ti, gold Au, silver Ag, copper Cu, or an alloy thereof, and the like, but not limited thereto.

The second electrode 125 is disposed on the second semiconductor layer 123. The second electrode 125 may be disposed on the upper surface of the second semiconductor layer 123. The second electrode 125 is an electrode for connecting the power line and the second semiconductor layer 123 electrically. The second electrode 125 may be included of a conductive material, e.g., a transparent conductive material such as indium tin oxide (ITO) or indium zinc oxide (IZO) and the like or an opaque conductive material such as titanium Ti, gold Au, silver Ag, copper Cu, or an alloy thereof, and the like, but not limited thereto.

Then an encapsulation film 126 surrounding the first semiconductor layer 121, the light emitting layer 122, the second semiconductor layer 123, the first electrode 124 and the second electrode 125 is disposed. The encapsulation film 126 may be included of an insulation material, and protect the first semiconductor layer 121, the light emitting layer 122 and the second semiconductor layer 123. Additionally, the encapsulation film 126 may have a contact hole that exposes the first electrode 124 and the second electrode 125, such that the first connection electrode CE1 and the second connection electrode CE2, and the first electrode 124 and the second electrode 125 connect electrically.

Further, a portion of the lateral surface of the first semiconductor layer 121 may be exposed from the encapsulation film 126. The light emitting diode 120 manufactured on a wafer may be separated from the wafer and transferred to the display panel PN. However, in the process where the light emitting diode 120 is separated from the wafer, a part of the encapsulation film 126 may be torn out. For example, a part of the encapsulation film 126, which is adjacent to the lower edge of the first semiconductor layer 121, may be torn out in the process where the light emitting diode 120 and the wafer separate, and as a result, a portion of the lateral surface of the lower side of the first semiconductor layer 121 may be exposed to the outside. However, even if a portion of the lower side of the light emitting diode 120 is exposed from the encapsulation film 126, a short circuit failure may decrease since the first connection electrode CE1 and the second connection electrode CE2 are formed after the second planarization layer 115b and the third planarization layer 115c covering the lateral surface of the first semiconductor layer 121 are formed.

Then the second planarization layer 115b and the third planarization layer 115c are disposed on the adhesive layer AD and the light emitting diode 120. The second planarization layer 115b may overlap a portion of the lateral surface of the plurality of light emitting diodes 120 to fix and protect the plurality of light emitting diodes 120. While the third planarization layer 115c is formed to cover a portion of the upper sides of the second planarization layer 115b and the light emitting diode 120, the third planarization layer 115c may have a contact hole to which the first electrode 124 and the second electrode 125 of the light emitting diode 120 are exposed. The first electrode 124 and the second electrode 125 of the light emitting diode 120 are exposed from the third planarization layer 115c, and the third planarization layer 115c is partially disposed in an area between the first electrode 124 and the second electrode 125, such that a short circuit failure decreases. The second planarization layer 115b and the third planarization layer 115c may be included of a single layer or multiple layers, and for example, included of photoresist or an acryl-based organic material, but not limited thereto. Further, according to the present disclosure, the second planarization layer 115b and the third planarization layer 115c are disposed, but the planarization layer may be included of a single layer and not limited thereto.

Further, the third planarization layer 115c may only cover the light emitting diode 120 and an area adjacent to the light emitting diode 120. The third planarization layer 115c may be formed only in an area where the bank BB is not formed. The third planarization layer 115c may be disposed in the area of the sub pixels SP, surrounded by the bank BB, and disposed in the form of an island. Thus, the bank BB may be disposed at one portion of the upper surface of the second planarization layer 115b, and the third planarization layer 115c may be disposed at the other portion of the upper surface of the second planarization layer 115b.

The first connection electrode CE1 and the second connection electrode CE2 are disposed on the third planarization layer 115c. The first connection electrode CE1 is an electrode connecting the second electrode 125 of the light emitting diode 120 and the power line electrically. The first connection electrode CE1 may electrically connect to the second electrode 125 of the light emitting diode 120 through the contact hole formed at the third planarization layer 115c.

The second connection electrode CE2 is an electrode electrically connecting the first electrode 124 of the light emitting diode 120 and the driving transistor DT. The second connection electrode CE2 may connect to the reflective layer RF of each of the plurality of sub pixels SP through the contact hole that is formed at the third planarization layer 115c, the second planarization layer 115b, the adhesive layer AD and the second passivation layer 114b. At this time, the reflective layer RF also connects to the source electrode SE of the driving transistor DT, such that the source electrode SE of the driving transistor DT and the first electrode 124 of the light emitting diode 120 electrically connect through the reflective layer RF and the second connection electrode CE2.

In the drawing, the first electrode 124, the second connection electrode CE2 and the reflective layer RF electrically connect to the source electrode SE of the driving transistor DT, but the first electrode 124, the second connection electrode CE2 and the reflective layer RF may also connect to the drain electrode DE of the driving transistor DT, and not be limited thereto.

The bank BB is disposed on the first connection electrode CE1 and the second connection electrode CE2, and on the second planarization layer 115b exposed from the third planarization layer 115c. The bank BB may be spaced a predetermined distance apart from the light emitting diode 120. For example, the bank BB may be disposed on the second planarization layer 115b in such a way that the bank BB is spaced a predetermined distance apart from the light emitting diode 120, or may cover a part of the second connection electrode CE2, which is formed in the contact holes of the third planarization layer 115c and the second planarization layer 115b. The bank BB may be included of an opaque material to reduce a color mixture among the plurality of sub pixels SP, and for example, included of black resin, but not limited thereto.

The protective layer 116 is disposed on the first connection electrode CE1, the second connection electrode CE2, and the bank BB. The protective layer 116, as a layer for protecting the configuration thereunder, may be included of a single layer or multiple layers of light transmitting epoxy, silicon oxide (SiOx) or silicon nitride (SiNx), but not limited thereto.

In the case of a display device 100 of the first embodiment, the adhesive force of the adhesive layer AD may be partially controlled to readily transfer the light emitting diode 120 from a donor, at a time of manufacturing the display device 100. Hereinafter, a manufacturing method of a display device 100 of a first embodiment is described with reference to FIGS. 6A to 6I.

FIGS. 6A to 6I are flowcharts for describing the manufacturing method of a display device of the first embodiment. In FIGS. 6A to 6I, a process of transferring the light emitting diode 120 to the plurality of first sub pixels SP1 of FIG. 4 is only illustrated for convenience of description. Though not illustrated in the drawings, the process of transferring the light emitting diode 120 to the first sub pixel SP1 is substantially the same as the process of transferring the light emitting diode 120 onto the second sub pixel SP2 and the third sub pixel SP3.

Referring to FIG. 6A, a wafer WF on which a plurality of light emitting diodes 120 are formed is disposed on a donor DN.

The wafer WF is a substrate on which a plurality of light emitting diodes 120 are formed. To form the plurality of light emitting diodes 120, a material constituting the plurality of light emitting diodes 120, such as gallium nitride (GaN), indium gallium nitride (InGaN) and the like, is formed on a wafer WF, to grow a crystalline layer, and then the crystalline layer is cut into an individual chip, and an electrode is formed. The wafer WF may be included of sapphire, silicon carbide (SiC), gallium nitride (GaN), zinc oxide (ZnO) and the like, but not limited thereto.

The donor DN is a transfer member transferring the plurality of light emitting diodes 120 on the wafer WF to the display panel PN. The plurality of light emitting diodes 120 are transferred onto the donor DN with a constant gap, such that the plurality of light emitting diodes 120 are transferred to the display panel PN at a time. The donor DN may include polymer resin having viscoelasticity such that the plurality of light emitting diodes 120 may adhere to the donor DN.

After the wafer WF and the donor DN are disposed to face each other, a part of the plurality of light emitting diodes 120 of the wafer WF may be selectively transferred toward the donor DN. For example, a laser LAS may be irradiated toward some of the plurality of light emitting diodes 120 on the wafer WF, and the light emitting diodes 120 may be detached from the wafer WF by the laser and attached onto the donor DN.

Referring to FIG. 6B together with FIG. 6A, the plurality of light emitting diodes 120 transferred onto the donor DN may be disposed in a plurality of first areas A1 of the donor DN. The plurality of first areas A1 correspond to a column in which a plurality of first sub pixels SP1 are disposed, and a plurality of light emitting diodes 120 in the plurality of first areas A1 may be transferred to the first sub pixels SP1. Each of the plurality of first areas A1 may be disposed with a first length D1 gap that is the same as a gap among the plurality of pixels PX. A distance from the edge of one side of one first area A1 to the edge of one side of an adjacent first area A1 may be the first length D1.

Additionally, the donor DN includes a plurality of second areas A2 and a plurality of third areas A3 together with the plurality of first areas A1. The plurality of second areas A2 correspond to a column in which the plurality of second sub pixels SP2 are disposed, and the plurality of third areas A3 correspond to a column in which the plurality of third sub pixels SP3 are disposed. Accordingly, in the case where the light emitting diode 120 is transferred to the plurality of second sub pixels SP2, a plurality of light emitting diodes 120 may be disposed in the plurality of second areas A2 of the donor DN. Similarly, in the case where the light emitting diode 120 is transferred to the plurality of third sub pixels SP3, a plurality of light emitting diodes 120 may be disposed in the plurality of third areas A3 of the donor DN.

Additionally, the plurality of light emitting diodes 120 transferred to the plurality of the first areas A1 of the donor DN may be transferred in such a way that the plurality of light emitting diodes 120 form a plurality of groups 120G. Each of the plurality of groups 120G includes a plurality of light emitting diodes 120. In the case where the donor DN is cemented/bonded with the display panel PN, each of the plurality of groups 120G may correspond to one sub pixel SP and an area adjacent to one sub pixel SP. For example, in the case where a group 120G is disposed in a first sub pixel SP1 and an area adjacent to the first sub pixel SP1, one group 120G may overlap in an area between the edge of one side of the first sub pixel SP1 and the edge of one side of the second sub pixel SP2 in the row direction, and in an area between the edge of one side of the first sub pixel SP1 and the edge of one side of an adjacent first sub pixel SP1 in the column direction.

A plurality of light emitting diodes 120 constituting one group 120G may be disposed with a gap less than a gap between sub pixels SP in the row direction and the column direction respectively. For example, a plurality of light emitting diodes 120 constituting one group 120G may be disposed with a gap less than the second length D2 in the column direction, and disposed with a gap less than the third length D3 in the row direction.

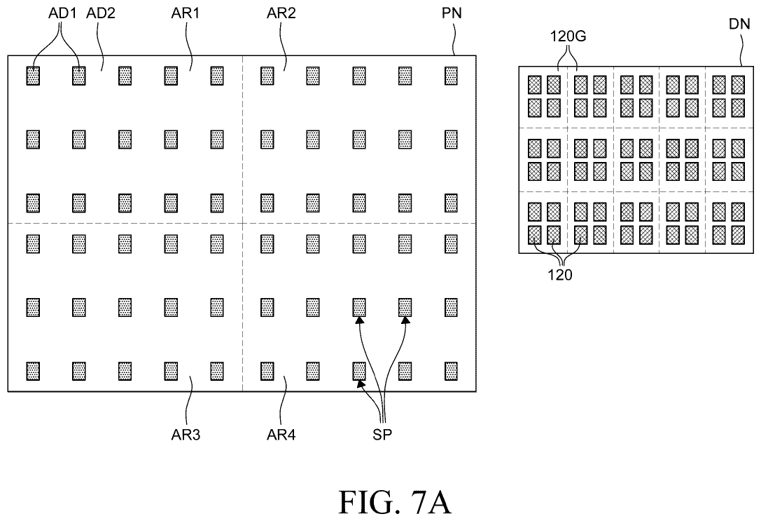

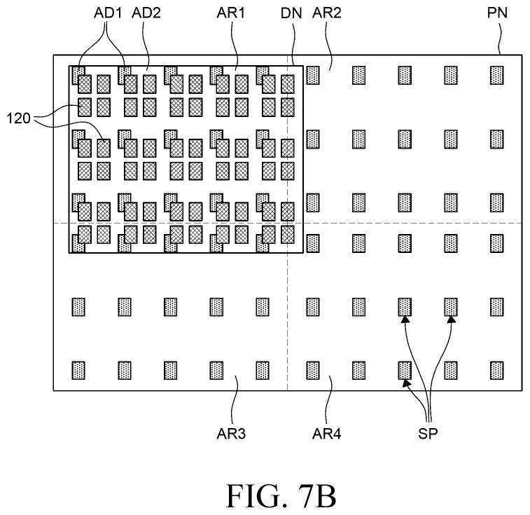

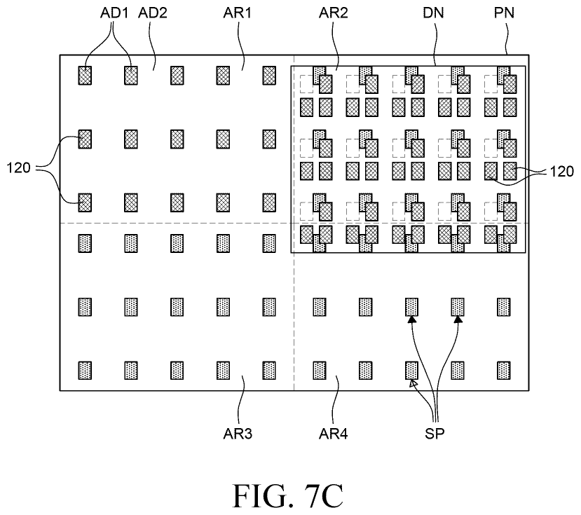

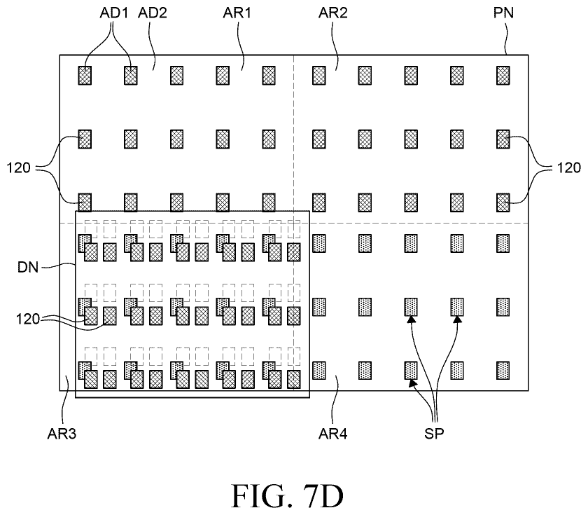

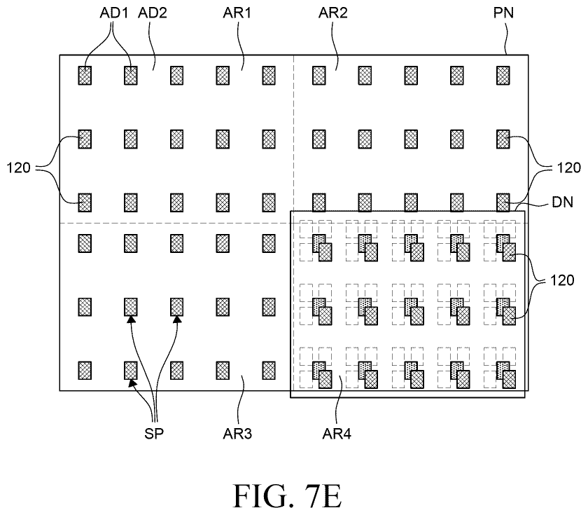

The number of light emitting diodes 120 included in each group 120 G may vary depending on the frequency at which one donor DN is used in succession in a transfer process. For example, in the case where one donor DN is used in succession n times in a transfer process where the light emitting diode 120 is transferred to the display panel PN, n numbers of light emitting diodes 120 may be disposed in one group 120G. In each of a plurality of transfer processes, each of the plurality of light emitting diodes 120 included in one group 120G may be transferred to a sub pixel SP at different positions. The adhesive layer AD of an area to which a plurality of light emitting diodes 120 is to be transferred only has an adhesive force selectively, such that only one of the plurality of light emitting diodes 120 included in one group 120G is transferred to the sub pixel SP selectively, and accordingly, the transfer process may be performed with one donor DN in succession, a plurality of times. Detailed description in relation to this is provided with reference to FIGS. 7A to 7E.

Then referring to FIGS. 6C and 6D, a mask MASK is disposed on the display panel PN having the adhesive layer AD, and light LT is irradiated. The mask MASK covering the area to which the plurality of light emitting diodes 120 is transferred is disposed, such that light may be irradiated only to the remaining area to which the plurality of light emitting diodes 120 is not to be transferred. Thus, the adhesive layer AD may be included of a plurality of first areas AD1 to which light LT is not irradiated, and a second area AD2 to which light LT is irradiated.

The plurality of first areas AD1 may respectively correspond to the plurality of sub pixels SP, and the second area AD2 may correspond to an area between the sub pixels SP. The second area AD2 of the adhesive layer AD, to which light LT is irradiated, may be cured and not have an adhesive force, and the plurality of first areas AD1 of the adhesive layer AD, to which light LT is not irradiated, may have an adhesive force. Thus, out of the adhesive layer AD formed on the front surface of the display panel PN, the adhesive layer AD of the plurality of first areas AD1 corresponding to the plurality of sub pixels SP only has an adhesive force, and the adhesive layer AD of the remaining second area AD2 does not have an adhesive force.

Further, referring to FIGS. 6E to 6H, the plurality of light emitting diodes 120 on the donor DN is transferred onto the adhesive layer AD of the display panel PN. Specifically, referring to FIGS. 6E and 6F, the display panel PN having the adhesive layer AD and the donor DN are arranged. After the donor DN is disposed in such a way that the plurality of light emitting diodes 120 of the donor DN and the adhesive layer AD of the display panel PN face each other, the display panel PN and the donor DN may be cemented/bonded. As the donor DN and the display panel PN are cemented/bonded, the adhesive layer AD of the display panel PN may overlap the plurality of light emitting diodes 120 of the donor DN as illustrated in FIG. 6F.

Further, referring to FIGS. 6G and 6H together, after the donor DN and the display panel PN are cemented, and the light emitting diodes 120 on the donor DN are transferred onto the adhesive layer AD, the donor DN may be detached from the display panel PN.

The light emitting diodes 120 having adhered onto the plurality of first areas AD1 of the adhesive layer AD may be detached from the donor DN and transferred to the display panel PN. However, the light emitting diodes 120 contacting onto the second area AD2 of the adhesive layer AD, which is cured previously in photolithography and the adhesive force of which is removed, may keep adhering to the donor DN. Accordingly, the light emitting diodes 120 contacting the plurality of first areas AD1 of the adhesive layer AD, which has an adhesive force since light LT is not irradiated thereto, may only be detached from the donor DN.

At this time, since the plurality of light emitting diodes are disposed on the donor DN such that the plurality of light emitting diodes may correspond only to the plurality of first areas A1, the plurality of light emitting diodes 120 of the donor DN may only overlap the plurality of first areas A1 where the plurality of first sub pixels SP1 of the display panel PN are disposed. Additionally, among the plurality of light emitting diodes 120 included in one group 120G, one light emitting diode 120 may only contact the first area AD1 in the first area A1, and be transferred to the display panel PN, and the remaining light emitting diodes 120 may contact the second area AD2 and be left on the donor DN. Further, since there is no light emitting diode 120 at a part of the donor DN, corresponding to the plurality of second areas A2 and the plurality of third areas A3, the light emitting diode 120 is not transferred onto the plurality of the first areas AD1 in the plurality of second areas A2 and the plurality of third areas A3. Thus, the plurality of light emitting diodes 120 may be transferred to all of the plurality of first sub pixels SP1 disposed in the plurality of first areas A1. Further, a plurality of light emitting diodes 120 remaining in each of the plurality groups 120G of the donor DN may be transferred to the display panel PN later in another transfer process.

Then the process of transferring the light emitting diodes 120 to the plurality of second sub pixels SP2 disposed in the plurality of second areas A2, and the process of transferring the light emitting diodes 120 to the plurality of third sub pixels SP3 disposed in the plurality of third areas A3 are performed repeatedly, such that the light emitting diodes 120 are transferred to all of the plurality of sub pixels SP. Specifically, as illustrated in FIGS. 6A and 6B, the plurality of light emitting diodes 120 on the wafer WF may be transferred to the plurality of second areas A2 of the donor DN, and as illustrated in FIGS. 6E to 6H, the light emitting diodes 120 of the donor DN may be transferred to the plurality of first areas AD1 in the plurality of second areas A2, e.g., onto the adhesive layer AD of the second sub pixel SP2. Additionally, the processes in FIGS. 6A and 6B, FIGS. 6E to 6H may be repeated in the same way such that the light emitting diodes 120 are also transferred to the plurality of third sub pixels SP3.

Finally, referring to FIG. 6I, after the process of transferring the light emitting diode 120 to all of the plurality of sub pixels SP is completed, light LT may be irradiated to the entire adhesive layer AD to cure the entire adhesive layer AD. Light may be irradiated to the entire adhesive layer AD with no separate mask MASK, such that the adhesive layer AD is cured throughout the plurality of first areas AD1 thereof.

Additionally, though not illustrated in the drawing, after the adhesive layer AD is cured, the second planarization layer 115b, the third planarization layer 115c, the bank BB, the first connection electrode CE1 and the second connection electrode CE2, the protective layer 116 and the like may be formed on the adhesive layer AD, to complete the manufacturing process of a display device 100.

Thus, in the display device 100 and the manufacturing method thereof of one embodiment, the transfer process may be carried out such that the plurality of light emitting diodes 120 may be disposed on the donor DN with a gap less than a gap among the plurality of sub pixels SP, but out of the adhesive layer AD of the display panel PN, the plurality of first areas AD1 corresponding to the plurality of sub pixels SP may only have an adhesive force. Accordingly, among the plurality of light emitting diodes 120 on the donor DN, light emitting diodes 120 arranged to overlap the plurality of sub pixels SP, e.g., light emitting diodes 120 arranged to overlap the plurality of first areas AD1 of the adhesive layer AD, may only be transferred selectively to the display panel PN, thereby reducing or minimizing the possibility of failure such as a transfer of the light emitting diode 120 to the display panel PN in an area outside the plurality of sub pixels SP.

Additionally, in the manufacturing method of a display device 100 of one embodiment, the process of a transfer with one donor DN may be performed in succession, a plurality of times, reducing time taken for the processing, and detailed description in relation to this is described with reference to FIGS. 7A to 7E.

FIGS. 7A to 7E are flowcharts for describing the manufacturing method of a display device of one embodiment. FIGS. 7A to 7E are views for describing the process of transferring the plurality of light emitting diodes 120 on the donor DN to the display panel PN in the case where the display panel PN has a greater size than the donor DN.

Referring to FIG. 7A, the display panel PN may have a greater size than the donor DN. For example, since the size of the display panel PN is about four times greater than that of the donor DN, four donors DN or four transfer processes may be required, for the light emitting diodes 120 to be transferred to the entire display panel PN. However, in the manufacturing method of a display device 100 of one embodiment, the adhesive layer AD has an adhesive force only in an area corresponding to the plurality of sub pixels SP, such that only a part of the plurality of light emitting diodes 120 disposed on one donor DN is transferred onto the display panel PN selectively, and a process of a transfer with one donor DN may be carried out a plurality of times.

Hereinafter, suppose that the size of the display panel PN is about four times greater than that of the donor DN for convenience of description, but the aspect ratios of the donor DN and the display panel PN are provided as an example, and not limited thereto.

At this time, the display panel PN where the light emitting diodes 120 are transferred to all of the plurality of sub pixels SP in four transfer processes may be included of four areas where one transfer process occurs, e.g., a first transfer area AR1, a second transfer area AR2, a third transfer area AR3 and a fourth transfer area AR4. In one transfer process, the light emitting diodes 120 may be transferred to any one of the first transfer area AR1, the second transfer area AR2, the third transfer area AR3 and the fourth transfer area AR4.

Additionally, before the light emitting diodes 120 are transferred to the display panel PN from the donor DN, a mask MASK is disposed on the adhesive layer AD formed entirely on the display panel PN, and light LT is irradiated, such that the adhesive layer AD may be formed into the plurality of first areas AD1 that correspond to the plurality of sub pixels SP and have an adhesive force, and the second area AD2 to which light LT is irradiated and which has no adhesive force. Accordingly, the adhesive layer AD may be formed entirely on the display panel PN, but may have an adhesive force partially only in the area corresponding to the plurality of sub pixels SP.

Additionally, all of the light emitting diodes 120 to be transferred to the first transfer area AR1, the second transfer area AR2, the third transfer area AR3 and the fourth transfer area AR4 may be disposed on the donor DN. For example, in the case where 15 sub pixels SP and 15 light emitting diodes 120 are transferred to each of the first transfer area AR1, the second transfer area AR2, the third transfer area AR3 and the fourth transfer area AR4, 15 groups 120G each including four light emitting diodes 120 that are respectively to be used in one of four transfer processes, e.g., 60 light emitting diodes 120, may be disposed on the donor DN.

Referring to FIG. 7B, the donor DN is cemented/bonded onto the first transfer area AR1 of the display panel PN, such that the plurality of light emitting diodes 120 on the donor DN may be transferred to the display panel PN. At this time, the plurality of light emitting diodes 120 on the donor DN may all contact the adhesive layer AD of the first transfer area AR1, but light emitting diodes 120 contacting the plurality of first areas AD1 having an adhesive force may only be transferred to the first transfer area AR1 selectively, and light emitting diodes 120 contacting the second area AD2 may be left on the donor DN.

Hereinafter, referring to FIG. 7C, while the donor DN is cemented/bonded onto the second transfer area AR2, the donor DN may be shifted such that any one of the plurality of light emitting diodes 120 in each of the plurality of groups 120G on the donor DN may contact the plurality of first areas AD1 of the adhesive layer AD and may be cemented/bonded onto the second transfer area AR2. The donor DN and the display panel PN may be arranged such that any one of the plurality of light emitting diodes 120 in each group 120G may overlap the first area AD1 of the adhesive layer AD, and the donor DN may be cemented/bonded with the display panel PN. Accordingly, the plurality of light emitting diodes 120 of the donor DN may contact the plurality of first areas AD1, and the light emitting diodes 120 may be transferred to the plurality of sub pixels SP in the second transfer area AR2. Additionally, the remaining light emitting diodes 120 contacting the second area AD2 of the second transfer area AR2 may keep adhering to the donor DN.

Referring to FIG. 7D, as descried in relation to the transfer process in the second transfer area AR2, the donor DN may be shifted and cemented/bonded onto the third transfer area AR3. Specifically, after the donor DN is arranged such that any one of the plurality of light emitting diodes 120 in each group 120G may correspond to the first area AD1 of the adhesive layer AD, the donor DN may be cemented onto the third transfer area AR3. Accordingly, any one of the light emitting diodes 120 in each group 120G may be transferred to the plurality of sub pixels SP in the third transfer area AR3.

Finally, referring to FIG. 7E, the donor DN may be arranged such that the light emitting diodes 120 remaining in each of the plurality of groups 120G on the donor DN may correspond to the first area AD1 of the adhesive layer AD, and may be cemented/bonded onto the fourth transfer area AR4. Accordingly, all of the plurality of light emitting diodes 120 disposed on the donor DN may be transferred to the display panel PN.

For example, for the light emitting diodes on the donor to be transferred to the plurality of sub pixels in the state where the entire adhesive layer has an adhesive force, it is beneficial for the light emitting diodes to be disposed only in an arrangement where the light emitting diodes correspond to the plurality of sub pixels on the donor. If the light emitting diodes are disposed on an area where the light emitting diodes do not correspond to the plurality of sub pixels, failure in which the light emitting diodes are transferred even to an area outside the sub pixels may occur in the process where the donor and the display panel are cemented/bonded. Against this backdrop, in the case where the display panel has a greater size than the donor, a display device may be manufactured by using a plurality of donors where a light emitting diode is disposed in an arrangement where the light emitting diode corresponds to each of the plurality of sub pixels. However, since a plurality of donors are used, the number of processes of selectively transferring light emitting diodes on a wafer to each donor may increase, and time taken for the processes may increase.

On the contrary, in the display device 100 and the manufacturing method of a display device 100 of one embodiment, a plurality of light emitting diodes 120 are transferred onto the donor DN at a time, and an area of the adhesive layer AD of the display panel PN, corresponding to the plurality of sub pixels SP, may only have an adhesive force selectively, such that a part of the plurality of light emitting diodes 120 on the donor DN may only be transferred selectively onto the sub pixels SP. Accordingly, the light emitting diodes 120 may be transferred to a plurality of areas of the display panel PN with one donor DN, thereby reducing the number of donors DN needed in the entire transfer processes. As a result, the number of processes of transferring the light emitting diodes 120 to the donor DN from the wafer WF and time taken for the processes may decrease.

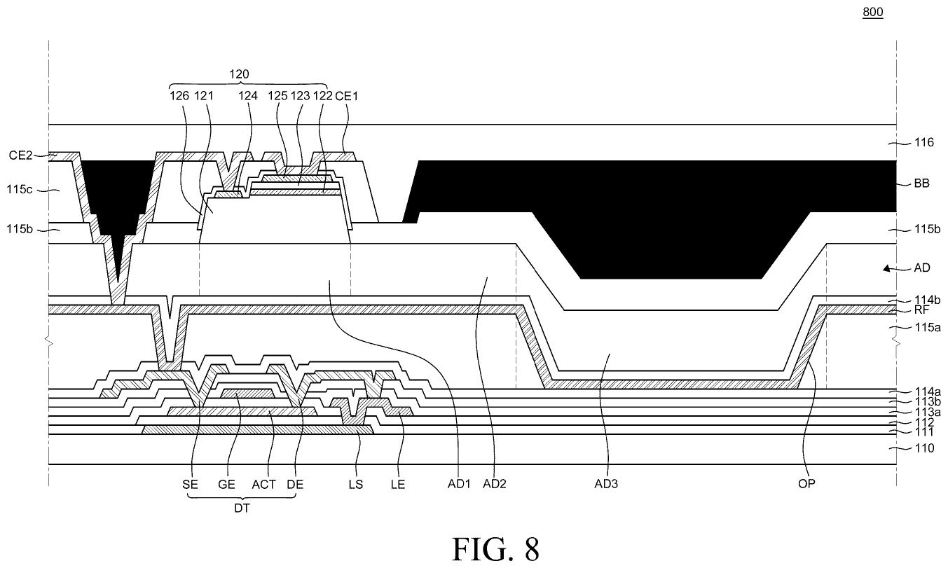

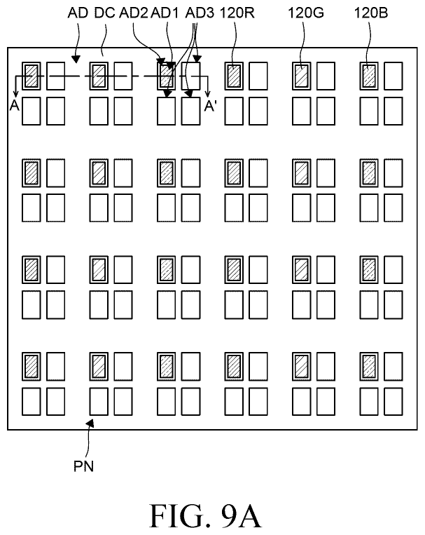

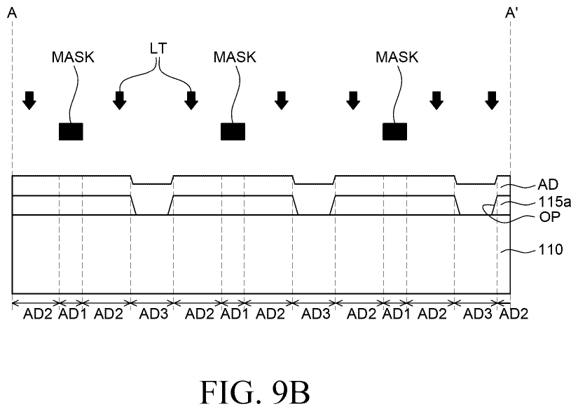

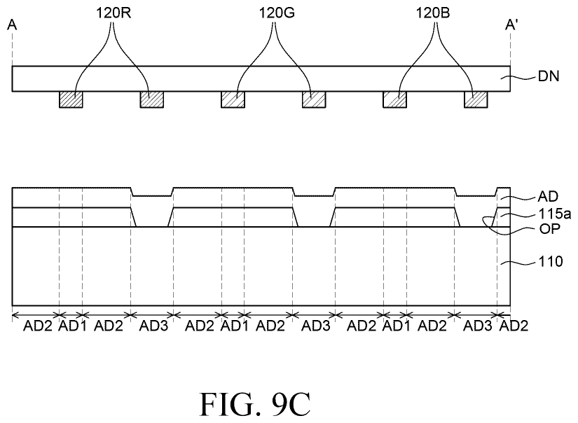

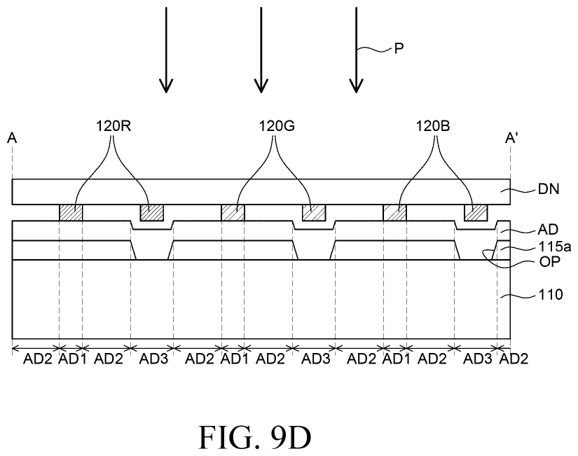

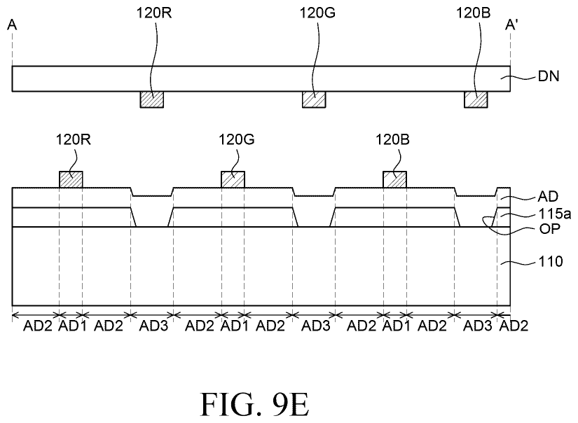

FIG. 8 is a cross-sectional view of a display device of a second embodiment. FIG. 9A is a plan view of a display device of second and third embodiments. FIGS. 9B to 9E are cross-sectional views of area A-A′ of FIG. 9A and flowcharts for describing a manufacturing method of area A-A′ of FIG. 9A.

As a result of comparison with the display device 100 of FIGS. 1 to 7E, the configuration of a display device 800 of FIG. 8 is substantially the same as that of the display device 100 of FIGS. 1 to 7E, except for a first planarization layer 115a and an adhesive layer AD, and accordingly, description of their identical configurations is omitted. For convenience of description, FIGS. 9B to 9E show a substrate 110, a first planarization layer 115a and an adhesive layer AD only, among the components of the display panel PN.

Referring to FIGS. 8 and 9A, a first planarization layer 115a in the form of an island may be disposed on the substrate 110 of the display device 800 of the second embodiment. The first planarization layer 115a may have an opening OP in a third area AD3 thereof that is an area where a light emitting diode 120 is not transferred. The adhesive layer AD may be disposed on the first planarization layer 115a. The adhesive layer AD may be included of a first area AD1 that is an area to which a light emitting diode 120 is transferred, a third area AD3 that is an area to which a light emitting diode 120 is not transferred, and a second area AD2 that is the remaining area. Herein, the transfer area may also be referred to as an adhesive area, and the non-transfer area may also be referred to as a non-adhesive area. The third area AD3 may overlap the light emitting diodes 120 that are not transferred to the display panel PN in the process where light emitting diodes 120 are transferred to the display panel PN from a donor DN.

The third area AD3 of the adhesive layer AD may form an opening formed at the first planarization layer 115a, and accordingly, may form a groove. The thickness of the third area AD3 may differ from the thickness of the first area AD1 and the thickness of the second area AD2.

Referring to FIGS. 9B to 9E, except for light emitting diodes 120R, 120G, 120B that are transferred to the first area AD1 among a plurality of light emitting diodes 120 having adhered onto the donor DN, the remaining light emitting diodes 120 must not be transferred to the display panel PN. To this end, as illustrated in FIG. 9B, a mask MASK covering the area to which the plurality of light emitting diodes 120 are transferred is disposed, as illustrated in FIG. 9B, such that light LT is irradiated only to the remaining area to which the plurality of light emitting diodes 120 are not to be transferred. Accordingly, the adhesive layer AD may be included of a plurality of first areas AD1 to which light LT is not irradiated, and second AD2 and third AD3 areas to which light LT is irradiated. As a result, the third area AD3 of the adhesive layer AD, to which light LT is irradiated, may be cured and have no adhesive force, and the first area AD1 of the adhesive layer AD, to which light LT is not irradiated, may have an adhesive force.

Then referring to FIGS. 9C to 9E, the donor DN is cemented/bonded with the display panel PN and then pressurized P, such that the light emitting diodes 120R, 120G, 120B may adhere only onto the plurality of first areas AD1 of the adhesive layer AD while the light emitting diodes 120 disposed on the third area AD3 may keep adhering to the donor DN.

The plurality of first areas AD1 of the adhesive layer AD, to which the plurality of light emitting diodes 120 adhere, may have a height greater than the height of the third area AD3 of the adhesive layer AD, such that the plurality of light emitting diodes 120 are transferred only to the plurality of first areas AD1. As illustrated in FIG. 9D, in the case where the upper surface of the plurality of first areas AD1 is higher than the upper surface of the third area AD3, the light emitting diodes 120 disposed on the third areas AD3 may not contact the third areas AD3, while the light emitting diodes 120 disposed on the plurality of first areas AD1 contact the first areas AD1, among the plurality of light emitting diodes 120. Accordingly, the light emitting diodes disposed on the third areas AD3 may keep adhering to the donor DN. Thus, in the case where the upper surface of the plurality of first areas AD1 of the adhesive layer AD, contacting the plurality of light emitting diodes 120, is formed to be higher than the upper surface of the third area AD3 of the adhesive layer AD, the plurality of light emitting diodes 120 may be fixed to the display panel PN more reliably.

In the display device 800 and the manufacturing method of a display device 800 of the second embodiment, the plurality of light emitting diodes 120 may be disposed on the donor DN with a narrow gap, but since the first planarization layer 115a of the third area AD3 as a non-transfer area of the display panel PN only has an opening, the transfer process may be carried out in the state where the upper surface of the adhesive layer AD of the third area AD3 is lower than the upper surface of the adhesive layer AD of the first area AD1. Additionally, since the plurality of first areas AD1, out of the adhesive layer AD of the display panel PN, only have an adhesive force, the light emitting diodes 120 arranged to overlap the plurality of first areas AD1 of the adhesive layer AD, among the plurality of light emitting diodes 120 on the donor DN, may only be transferred to the display panel PN selectively, thereby reducing or minimizing the possibility of failure in which the light emitting diodes 120 are transferred to the display panel PN in a non-transfer area.

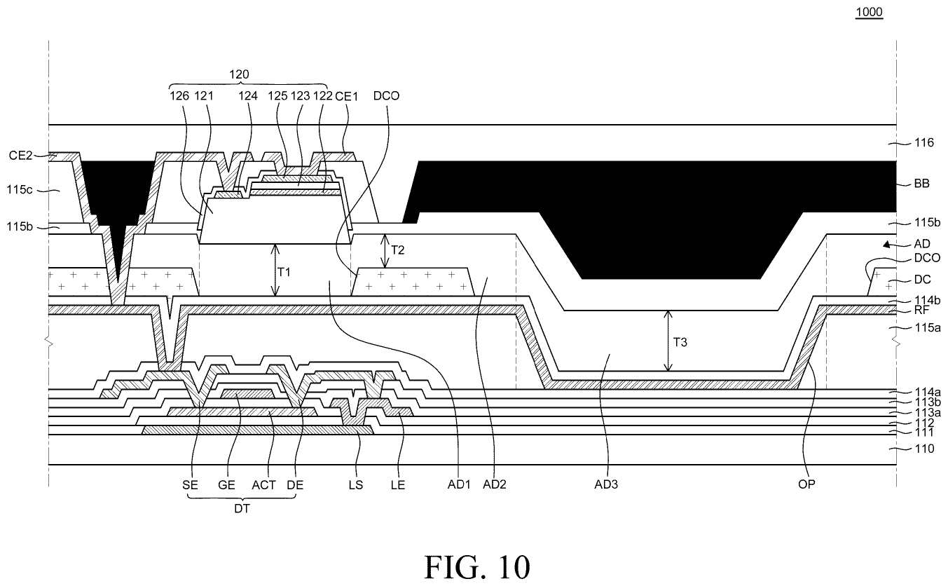

FIG. 10 is a plan view of the display device of the third embodiment. As a result of comparison with the display device 800 of FIG. 8, the configuration of a display device 1000 of FIG. 10 is substantially the same as that of the display device 800 of FIG. 8, except for a step formation layer DC and an adhesive layer AD, and accordingly, description of their identical configurations is omitted.

Referring to FIG. 10, the step formation layer DC may be disposed on the substrate 110 of the display device 1000 of the third embodiment. Specifically, the step formation layer DC may be disposed on the second passivation layer 114b. The step formation layer DC may have an opening DCO in an area where the step formation layer DC overlaps the light emitting diodes 120 or is adjacent to the light emitting diodes 120.

The adhesive layer AD may be disposed on the step formation layer DC. At this time, the adhesive layer AD may be included of a first area AD1 having a first thickness T1 that is relatively thick and a second area AD2 having a second thickness T2 that is less than the first thickness T1, because of the opening DCO formed at the step formation layer DC.

Since the first area AD1 of the adhesive layer AD is formed while filling the opening DCO formed at the step formation layer DC, the first area AD1 of the adhesive layer AD may have the first thickness T1 that is relatively thick. Since the second area AD2 of the adhesive layer AD is formed while covering the upper surface of the step formation layer DC that is disposed with the opening DCO between the second area AD2 and the step formation layer DC, the second area AD2 of the adhesive layer AD may have the second thickness T2 that is less than the first thickness T1. The upper end of the first area AD1 may be lower than the upper end of the second area AD2. The step formation layer DC may be included of an organic material such as an acryl-based material or polyimide or an inorganic material such as silicon oxide (SiOx), but not limited thereto.

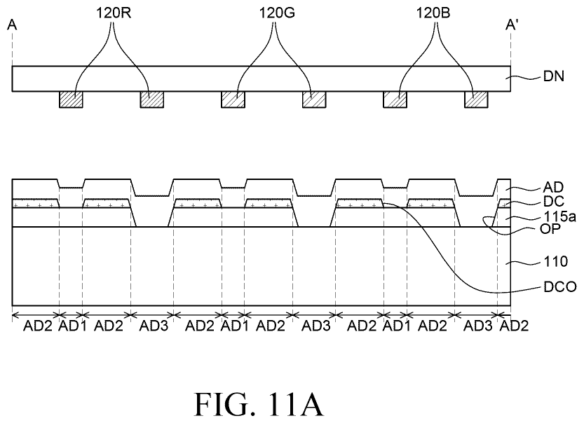

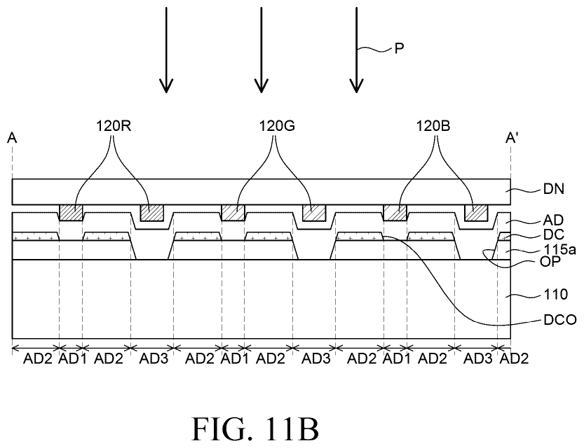

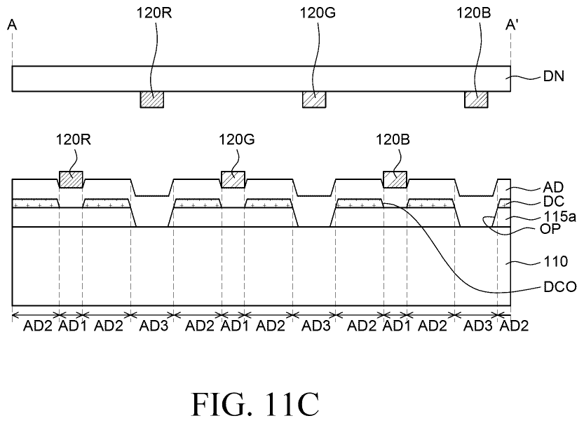

The plurality of first areas AD1 of the adhesive layer AD, contacting the plurality of light emitting diodes 120, may be disposed on the opening DCO. Additionally, the second area AD2 of the adhesive layer AD, to which the plurality of light emitting diodes 120 are not transferred, may be disposed in an area where the second area AD2 does not overlap the opening DCO. In the display device 1000 of the third embodiment, the plurality of first areas AD1 of the adhesive layer AD may include a transfer area to which the light emitting diodes 120 are transferred, and a non-transfer area to which the light emitting diodes 120 are not transferred. Herein, the non-transfer area may also be referred to as a non-attachment area. At this time, the adhesive layer AD may have a different height in the transfer area and the non-transfer area. Description in relation to this is provided hereinafter with reference to FIGS. 11A to 11C.

Referring to FIG. 10, in the display device 1000 of the third embodiment, the adhesive layer AD may further include a third area AD3 that is an area to which the light emitting diodes 120 are not transferred and which overlaps the opening DCO. Accordingly, the adhesive layer AD may include a transfer area to which the light emitting diodes 120 are transferred and a non-transfer area to which the light emitting diodes 120 are not transferred. Herein, the transfer area may also be referred to as an attachment area, and the non-transfer area may also be referred to as a non-attachment area. The third area AD3 may overlap the light emitting diodes 120 that are not transferred to the display panel PN in the process where the light emitting diodes 120 are transferred to the display panel PN from the donor DN.

The upper end of the first area AD1 may be higher than the upper end of the third area AD3, but not limited thereto. In the transfer process, among the plurality of light emitting diodes 120 having adhered onto the donor DN, the remaining light emitting diodes 120 must not be transferred to the display panel PN except for the light emitting diodes 120 that are transferred to the first area AD1. To this end, light may be irradiated to the third area AD3, with a mask. Accordingly, the third area AD3 of the adhesive layer AD, to which light LT is irradiated, may be cured and have no adhesive force, and the first area AD1 to which light LT is not irradiated may have an adhesive force. Thus, out of the adhesive layer AD formed on the front surface of the display panel PN, the adhesive layer AD of the plurality of first areas AD1 corresponding to the plurality of sub pixels SP has an adhesive force, and the adhesive layer AD of the third area to which the light emitting diodes 120 are not transferred has no adhesive force. The third area AD3 may be shaped into a planar rectangle or a planar circle, but not limited thereto.

Then as the donor DN is cemented/bonded with the display panel PN, the light emitting diodes 120R, 120G, 120B may adhere only onto the plurality of first areas AD1 of the adhesive layer AD, and the light emitting diodes 120 contacting the third area AD3 may keep adhering to the donor DN.

In the display device 1000 of the third embodiment, since the plurality of first areas AD1 of the adhesive layer AD, to which the plurality of light emitting diodes 120 adhere, has a thickness T1 greater than the thickness T2 of the second area AD2 and the thickness T3 of the third area AD3, the adhesive force of the plurality of first areas AD1 may be improved further. The plurality of first areas AD1 of the adhesive layer AD, contacting the plurality of light emitting diodes 120, are thicker than the other areas of the adhesive layer AD, such that the plurality of light emitting diodes 120 may be fixed to the display panel PN more reliably.

Further, the third area AD3 may have a thickness T3 the same as the thickness T1 of the first area AD1, and may have a high adhesive force like the first area AD1. However, a problem may occur in the case where the step formation layer DC is disposed under the third area AD3, and the height of the upper portion of the adhesive layer AD of the third area AD3 becomes similar to the height of the upper portion of the adhesive layer AD of the second area AD2. For example, in the process where the light emitting diodes 120 are transferred to the display panel PN from the donor DN by using pressure, the light emitting diodes 120 that must not be transferred may be transferred to the third area AD3 since the upper portion of the adhesive layer AD of the third area AD3, which is cured by light LT and loses an adhesive force, is broken, and the adhesive layer AD that has an adhesive force and is disposed in the lower portion of the adhesive layer AD of the third area AD3 is exposed. To prevent this from happening, in the display device 1000 of the third embodiment, the upper end of the adhesive layer AD of the third area AD3 is formed to be lower than the upper end of the second area AD2, such that a transfer based on pressure may be prevented, and light LT is irradiated to the third area AD3 such that the adhesive force of the adhesive layer AD may be removed. The surface area of the third area AD3 may be greater than, or less than, or the same as that of the opening DCO.

Referring to FIG. 10, the display device 1000 of the third embodiment may have a first planarization layer 115a with an opening OP, under the third area AD3 that is the non-attachment area of the light emitting diodes 120, and have a step formation layer DC, in an adjacent area of the first area AD1 that is the attachment area of the light emitting diodes 120. Accordingly, a step between the upper surface of the first area AD1 and the upper surface of the third area AD3 in the third embodiment may be greater than a step between the upper surface of the first area AD1 and the upper surface of the third area AD3 in the second embodiment. As a result, a transfer pressure between the light emitting diode 120 and the third area AD3 decreases, thereby preventing an excessive transfer of the third area AD3.

FIGS. 11A to 11C are flowcharts for describing a manufacturing method of area A-A′ of FIG. 9A in relation to the display device. As a result of comparison with the display device 800 of FIGS. 9B to 9E, the configuration of a display device of FIGS. 11A to 11C is substantially the same as that of the display device 800 of FIGS. 9B to 9E, except for a step DC and an adhesive layer AD, and accordingly, description of their identical configurations is omitted. For convenience of description, FIGS. 11A to 11C show a substrate 110, a step formation layer DC and an adhesive layer AD only, among the components of the display panel PN.

Referring to FIGS. 11B and 11C, in the process where the light emitting diodes 120 are transferred to the display panel PN from the donor DN, the light emitting diodes 120 are not transferred and left on the donor DN in the third area AD3 disposed in area A-A′. In the third embodiment, the adhesive layer AD may have a different surface area in the plurality of first areas AD1 and the plurality of third areas AD3. The thickness T1 of the adhesive layer AD in the first area AD1 may be the same as or greater than the thickness T2 in the second area AD2 and the thickness T3 in the third area AD3.

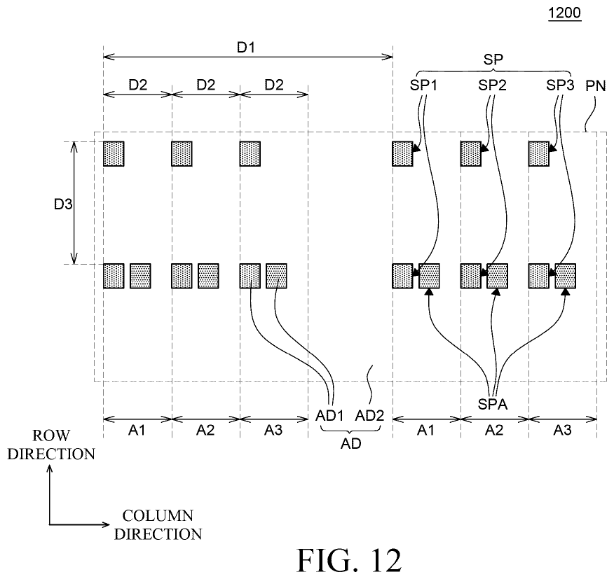

FIG. 12 is a plan view of a display device of a fourth embodiment. As a result of comparison with the display device 800 of FIGS. 8 to 9E, the configuration of a display device 1200 of FIG. 12 is substantially the same as that of the display device 800 of FIGS. 8 to 9E, except for a plurality of sub pixels SP and an adhesive layer AD, and accordingly, description of their identical configurations is omitted. For convenience of description, FIG. 12 shows an adhesive layer AD and a plurality of sub pixels SP only.

Referring to FIG. 12, an additional sub pixel SPA may be further disposed on the substrate 110. The additional sub pixel SPA is a component for transferring a light emitting diode 120 additionally and repairing a defective sub pixel SP, at a time of failure in a transfer of a light emitting diode 120 to the sub pixel SP. The additional sub pixel SPA may be disposed near a part of the plurality of sub pixels SP. For example, the additional sub pixel SPA may be disposed between the plurality of sub pixels SP in a part of a plurality of rows. However, in FIG. 12, the disposition of the additional sub pixel SPA is provided as an example, and not limited thereto.

The donor DN and the display panel PN may be cemented/bonded, and the light emitting diodes 120 are transferred to the plurality of sub pixels SP, and then a sub pixel to which a transfer failure occurs may be detected. If the light emitting diodes 120 are not transferred to the first sub pixel SP1 among the plurality of sub pixels SP, or the light emitting diodes are transferred outside their proper positions, the light emitting diodes 120 may be transferred to the additional sub pixel SPA adjacent to the first sub pixel SP1 to replace with a defective sub pixel SP.

For the light emitting diodes 120 to be transferred to the additional sub pixel SPA, a part of the adhesive layer AD, corresponding to the additional sub pixel SPA, may also be formed into the first area AD1. For example, before the plurality of light emitting diodes 120 are transferred to the display panel PN, a mask MASK covering the areas of the plurality of sub pixels SP and additional sub pixels SPA is disposed, and light LT is irradiated, to remove the adhesive force of the third area AD3 (see FIG. 9A) of the adhesive layer AD. Additionally, the plurality of first areas AD1 to which light LT is not irradiated, e.g., a part of the adhesive layer AD, overlapping the plurality of sub pixels SP and the plurality of additional sub pixels SPA, may still have an adhesive force. Accordingly, after a transfer failure of the display panel PN is detected, the light emitting diodes 120 may be transferred onto the first areas AD1 of the additional sub pixels SPA, having an adhesive force, to repair a defective sub pixel SP. Then the adhesive layer AD1 may be cured by irradiating light LT again to the plurality of first areas AD1, second areas AD2 and third areas AD3, after the repair is completed.

Accordingly, in the display device 1200 of the fourth embodiment, in the case where the additional sub pixels SPA for repairs are formed, the adhesive layer AD corresponding to the additional sub pixels SPA may also be formed into the first area AD1, such that the light emitting diodes 120 are transferred to the display panel PN in an additional transfer process. Thus, the adhesive layer AD may be designed in a variety of structures considering a repair process and the like.

The exemplary embodiments of the present disclosure can also be described as follows:

According to an aspect of the present disclosure, there is provided a display device. The display device includes a substrate in which a pixel including a plurality of sub pixels is included. The display device further includes a first planarization layer disposed on the substrate and configured to have an opening. The display device further includes an adhesive layer disposed on the first planarization layer. The display device further includes a plurality of light emitting diodes disposed on the adhesive layer in each of the plurality of sub pixels. The adhesive layer comprises a plurality of first areas configured to overlap the plurality of light emitting diodes, a plurality of non-attachment areas disposed respectively to be adjacent to the first areas, and a second area as a remaining part, except for the plurality of first areas and non-attachment areas.

The display device may further include a step formation layer disposed on the first planarization layer.

The step formation layer may have an opening in an area where the step formation layer overlaps the plurality of first areas and non-attachment areas.

The step formation layer may be disposed in a second area adjacent to the plurality of first areas.

The plurality of first areas may have a greater thickness than the second area or the non-attachment area.

A light emitting diode may be not disposed in the plurality of non-attachment areas.

The plurality of non-attachment areas may include a portion that is exposed to light and cured.

The plurality of first areas may have a greater adhesive force than the plurality of non-attachment areas.

According to another aspect of the present disclosure, there is provided a manufacturing method of a display device. The manufacturing method of a display device includes transferring a plurality of light emitting diodes on a wafer to a donor. The manufacturing method of a display device further includes disposing a first planarization layer on a substrate of a display panel. The manufacturing method of a display device further includes disposing an adhesive layer on the substrate and the first planarization layer. The manufacturing method of a display device further includes disposing a mask on the adhesive layer and irradiating light. The manufacturing method of a display device further includes transferring the plurality of light emitting diodes on the donor to a display panel. The adhesive layer is comprised of a plurality of first areas that overlap the mask, and a non-attachment area which is exposed from the mask and to which light is irradiated, and among the plurality of light emitting diodes, only light emitting diodes contacting the plurality of first areas are transferred to the display panel.

Disposing a mask on the adhesive layer and irradiating light may include blocking light proceeding toward the plurality of first areas to prevent the plurality of first areas from being cured, and irradiating light to the non-attachment area and curing the non-attachment area.

The manufacturing method of a display device may further include transferring the plurality of light emitting diodes to the display panel, and then irradiating light to the adhesive layer and curing the entire adhesive layer.

The adhesive layer of the plurality of first areas may have a greater thickness than an adhesive layer of a second area and the adhesive layer of the non-attachment area, and the plurality of first areas may have a greater adhesive force than the second area.

The display panel may include a plurality of sub pixels, and the plurality of first areas may overlap the plurality of sub pixels.

The plurality of light emitting diodes transferred to the donor from the wafer may form a plurality of groups, and in transferring the plurality of light emitting diodes on the donor to a display panel, each of the plurality of groups may be disposed to overlap each of the plurality of sub pixels and an area adjacent to the plurality of sub pixels.

At least one of a plurality of light emitting diodes included in each of the plurality of groups may overlap the plurality of first areas, and the remaining light emitting diodes may overlap the non-attachment area.

The display panel may further include additional sub pixels disposed among the plurality of sub pixels, and the plurality of first area of the adhesive layer may correspond to the additional sub pixels.

The manufacturing method of a display device may further include transferring the plurality of light emitting diodes to a display panel, and then detecting a transfer failure of the plurality of light emitting diodes. The manufacturing method of a display device may further include transferring the light emitting diodes to the additional sub pixels adjacent to sub pixels to which a transfer failure occurs. Additionally, the manufacturing method of a display device may further include curing the entire adhesive layer.

The manufacturing method of a display device may further include disposing a step formation layer on the first planarization layer. The manufacturing method of a display device may further include patterning the step formation layer and forming an opening. Additionally, the manufacturing method of a display device may further include disposing an adhesive layer on the step formation layer.

The manufacturing method of a display device may further include patterning a non-transfer area of the first planarization area and forming an opening.

Although the exemplary embodiments of the present disclosure have been described in detail with reference to the accompanying drawings, the present disclosure is not limited thereto and may be implemented in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a pixel, the pixel including a plurality of sub pixels;
a first planarization layer disposed on the substrate;
an opening in the first planarization layer;
an adhesive layer disposed on the first planarization layer; and
a plurality of light emitting diodes disposed on the adhesive layer in each of the plurality of sub pixels,
wherein the adhesive layer comprises a plurality of first areas configured to overlap the plurality of light emitting diodes, a plurality of non-attachment areas disposed respectively to be adjacent to the first areas, and a second area as a remaining part, except for the plurality of first areas and non-attachment areas.

2. The display device of claim 1, further comprising a step formation layer disposed on the first planarization layer.

3. The display device of claim 2, wherein the step formation layer has an opening in an area where the step formation layer overlaps the plurality of first areas and non-attachment areas.

4. The display device of claim 3, wherein the step formation layer is disposed in a second area adjacent to the plurality of first areas.

5. The display device of claim 1, wherein the plurality of first areas has a greater thickness than the second area or the non-attachment area.

6. The display device of claim 5, wherein a light emitting diode is not disposed in the plurality of non-attachment areas.

7. The display device of claim 5, wherein the plurality of non-attachment areas comprises a portion that is exposed to light and cured.

8. The display device of claim 5, wherein the plurality of first areas has a greater adhesive force than the plurality of non-attachment areas.

9. The display device of claim 1, wherein an upper end of the first area is lower than an upper end of the second area.

10. The display device of claim 1, wherein an upper end of the first area is higher than an upper end of the non-attachment area.

11. A manufacturing method of a display device, comprising:
transferring a plurality of light emitting diodes on a wafer to a donor;
disposing a first planarization layer on a substrate of a display panel;
disposing an adhesive layer on the substrate and the first planarization layer;
disposing a mask on the adhesive layer and irradiating light; and
transferring the plurality of light emitting diodes on the donor to a display panel,
wherein the adhesive layer is comprised of a plurality of first areas that overlap the mask, and a non-attachment area which is exposed from the mask and to which light is irradiated, and
wherein among the plurality of light emitting diodes, only light emitting diodes contacting the plurality of first areas are transferred to the display panel.

12. The manufacturing method of claim 11, wherein disposing a mask on the adhesive layer and irradiating light comprises:
blocking light proceeding toward the plurality of first areas to prevent the plurality of first areas from being cured, and irradiating light to the non-attachment area and curing the non-attachment area.

13. The manufacturing method of claim 12, further comprising: transferring the plurality of light emitting diodes to the display panel, and then irradiating light to the adhesive layer and curing the entire adhesive layer.

14. The manufacturing method of claim 12, wherein the adhesive layer of the plurality of first areas has a greater thickness than an adhesive layer of a second area and the adhesive layer of the non-attachment area, and
wherein the plurality of first areas has a greater adhesive force than the second area.

15. The manufacturing method of claim 11, wherein the display panel comprises a plurality of sub pixels, and
wherein the plurality of first areas overlaps the plurality of sub pixels.

16. The manufacturing method of claim 15, wherein the plurality of light emitting diodes transferred to the donor from the wafer form a plurality of groups, and
in transferring the plurality of light emitting diodes on the donor to a display panel, each of the plurality of groups is disposed to overlap each of the plurality of sub pixels and an area adjacent to the plurality of sub pixels.

17. The manufacturing method of claim 16, wherein at least one of a plurality of light emitting diodes included in each of the plurality of groups overlaps the plurality of first areas, and the remaining light emitting diodes overlap the non-attachment area.

18. The manufacturing method of claim 15, wherein the display panel further comprises additional sub pixels disposed among the plurality of sub pixels, and
wherein the plurality of first area of the adhesive layer correspond to the additional sub pixels.

19. The manufacturing method of claim 18, further comprising:
transferring the plurality of light emitting diodes to a display panel, and then detecting a transfer failure of the plurality of light emitting diodes;
transferring the light emitting diodes to the additional sub pixels adjacent to sub pixels to which a transfer failure occurs; and
curing the entire adhesive layer.

20. The manufacturing method of claim 11, further comprising:
disposing a step formation layer on the first planarization layer;
patterning the step formation layer and forming an opening; and
disposing an adhesive layer on the step formation layer.

21. The manufacturing method of claim 11, further comprising: patterning a non-transfer area of the first planarization area and forming an opening.

22. The manufacturing method of claim 14, wherein an upper end of the first area is lower than an upper end of the second area.

23. The manufacturing method of claim 11, wherein an upper end of the first area is higher than an upper end of the non-attachment area.
